(19) United States
(12) Patent Application Publication
(10) Pub. No.: US 2022/0180041 A1
(43) Pub. Date: Jun. 9, 2022

(54) IMAGE GENERATION METHOD

(71) Applicant: TASMIT, INC., Yokohama (JP)

(72) Inventor: Kotaro MARUYAMA, Yokohama (JP)

(21) Appl. No.: 17/598,212

(22) PCT Filed: Mar. 6, 2020
(86) PCT No.: PCT/JP2020/009695

§ 371 Date: Sep. 24, 2021

(30) Foreign Application Priority Data
Mar. 28, 2019 (JP) 2019-062767

(51) Int. Cl. G06F 30/398; G06F 30/392; G06F 30/10; G06T 7/00

(52) U.S. Cl. CPC G06F 30/398; G06F 30/392; G06T 2207/10061; G06T 7/0004; G06F 30/10

(57) ABSTRACT

The image generation method includes: selecting a clip area (C1) in which a pattern having a uniqueness value higher than the threshold value exists; determining a first specific point (P1) which is a specific point existing in the selected clip area (C1); generating an image of a first point (F1) on a chip by a scanning electron microscope, the first point (F1) being specified by coordinates of the first specific point (P1); calculating a vector (V1) indicating deviation between the first specific point (P1) and the first point (F1) on the image; determining a second specific point (P5) in a clip area in which a pattern having a uniqueness value equal to or less than the threshold value exists; and correcting coordinates of the second specific point (P5) based on the vector (V1).

### TECHNICAL FIELD

The present invention relates to a method of imaging a specific point on a wafer using a scanning electron microscope, and more particularly to a method of imaging a specific point, such as a hotspot having a high possibility of defect.

### BACKGROUND ART

With the tendency of finer semiconductor devices, high-resolution lithography technique, optical proximity effect correction technique, and the like have been developed. However, it is still difficult to produce a designed circuit pattern on a wafer accurately using lithography techniques, photomasks, photoresist patterns, and processing techniques.

Due to fluctuations in optical conditions of the lithography and fluctuations in processing conditions in the pattern processing, an unpredictable change in pattern shape occurs depending on designed circuit pattern shape. Of pattern shapes, a pattern shape having a vulnerability that can affect an electrical operation of a semiconductor device is called hotspot. In the development of semiconductor devices, in order to shorten the period of development and to stabilize manufacturing of devices, it is very important to quickly find hotspots, extract information, such as shapes and sizes, of the hotspots, and modify design data or photomask patterns based on the information.

The shape of pattern created on photoresist and the shape of pattern processed using the pattern created on the photoresist can be verified using an image of the pattern. With the tendency of finer semiconductor devices, a line width of pattern is 30 nm or less. Therefore, a scanning electron microscope having a resolution of several nm or less is generally used for pattern image generation.

A die-to-database method is a typical method for detecting hotspots from an image obtained. The die-to-database method includes detecting hotspots by comparing pattern shapes on design data with an image of patterns on a wafer. Further, the die-to-database method makes it possible to measure the pattern shape according to a predetermined rule by using an amount of characteristics of pattern on the design data.

A field of view (FOV) of the scanning electron microscope is about 100 λm at a maximum. Therefore, it is not realistic to generate images of all patterns on a chip having a maximum dimension of 20 mm or more by the scanning electron microscope within a given time. Therefore, a method of generating only images of hotspots predicted in advance by simulation is adopted. This simulation can predict a shape of pattern to be created on a wafer by using design data for photomask patterns and optical conditions of lithography. Specifically, hotspots can be generated in the simulation by intentionally changing the optical conditions of lithography. This simulation is used to predict patterns that can generate hotspots, but on the other hand, millions of hotspots may be detected per design data of a single semiconductor chip.

In order to complete the image generation of these enormous numbers of hotspots in a shortest time, images with a small field of view (FOV) of several hundred nm to several μm are used. In order to keep the hotspots within the field of view of the image, the size of field of view cannot be smaller than a positioning precision of image generation of the scanning electron microscope. Further, in repeating patterns, if the amount of misalignment exceeds half the amount of pattern pitch, it becomes difficult to obtain a correct result of pattern matching.

### CITATION LIST

### Patent Literature

Patent document 1: Japanese laid-open patent publication No. 2002-33365

### SUMMARY OF INVENTION

### Technical Problem

Usually, in the die-to-database method, an alignment process is performed in which a coordinate system defined on a wafer and a coordinate system defined in design data are matched before a hotspot image is generated. This alignment process includes generating an image of a reference pattern for alignment on a wafer and matching the reference pattern on the image with a corresponding CAD pattern. However, when the image is generated using an electron beam, the image may be shifted in position due to causes described below.

1. Change in travelling path of the electron beam due to fluctuation of magnetic field caused by a motor of a specimen stage or disturbance
2. Charging up on a wafer before electron beam irradiation
3. Charging up on a wafer surface as a result of electron beam irradiation
4. Measurement error of a displacement measuring device used to measure the position of the specimen stage
5. Positional deviation between the reference pattern used for alignment and the actual pattern in the chip
6. Positional deviation of the actual pattern due to distortion of the wafer caused by wafer heat treatment

All of these positional shifts may be observed in a wafer surface and a chip surface as non-linear local fluctuations. In the above alignment process performed for each wafer or each chip before inspection, these positional shifts cannot be completely corrected.

Therefore, the present invention provides a method of accurately determining a position of a specific point, such as a hotspot, and generating an image of the specific point.

### Solution to Problem

In one aspect, there is provided an image generation method comprising: setting clip areas centered on specific points on a design data of patterns; calculating uniqueness values each indicating an aperiodicity of a pattern in each of the clip areas; comparing the uniqueness values with a preset threshold value; selecting, from the clip areas, a clip area in which a pattern having a uniqueness value higher than the threshold value exists; determining a first specific point which is a specific point existing in the selected clip area; generating an image of a first point on a chip by a scanning electron microscope, the first point being specified by coordinates of the first specific point; calculating a vector indicating deviation between the first specific point and the first point on the image; correcting coordinates of a second specific point based on the vector, the second specific point being in a clip area in which a pattern having a uniqueness value equal to or less than the threshold value exists; and generating an image of a second point on the chip by the scanning electron microscope, the second point being specified by the corrected coordinates.

In one aspect, the image generation method further comprises: performing a first matching between a pattern appearing on the image of the first point on the chip and a corresponding CAD pattern; and performing a second matching between a pattern appearing on the image of the second point on the chip and a corresponding CAD pattern; wherein a search range for searching for the corresponding CAD pattern in the second matching is narrower than a search range for searching for the corresponding CAD pattern in the first matching.

In one aspect, the selected clip area comprises at least three clip areas selected from the clip areas; the first specific point comprises at least three first specific points existing in the at least three clip areas, respectively; the first point comprises at least three first points on the chip specified by coordinates of the at least three first specific points; and the vector comprises vectors indicating deviations between the at least three first specific points and the at least three first points on the image.

In one aspect, the second specific point is surrounded by the at least three first specific points.

In one aspect, the second specific point is located outside a figure having vertices defined by the at least three first specific points.

In one aspect, correcting the coordinates of the second specific point based on the vectors comprises: calculating a correction parameter necessary for converting a figure specified by the at least three first specific points into a figure specified by the at least three first points on the image; and correcting the coordinates of the second specific point using the correction parameter.

In one aspect, a distance from the first specific point to the second specific point is equal to or less than a preset distance.

In one aspect, correcting the coordinates of the second specific point based on the vector comprises correcting the coordinates of the second specific point by moving the second specific point in a direction indicated by the vector by a distance indicated by the vector.

### Advantageous Effects of Invention

A pattern with a high uniqueness value is likely to succeed in matching with an actual pattern on an image. This is because the pattern having a high uniqueness value has a distinguishing shape that is different from surrounding patterns. In contrast, a pattern having a low uniqueness value has the same shape as those of surrounding patterns, and therefore tends to fail to match with an actual pattern on an image. According to the present invention, coordinates of other specific point are corrected based on the position information of three specific points close to patterns having the high uniqueness values. Since the position information of the specific points used for the correction is highly reliable, the reliability of the corrected coordinates is also improved.

Therefore, this method can accurately determine a position of a specific point, such as a hotspot.

### BRIEF DESCRIPTION OF DRAWINGS

FIG. 1 is a schematic view showing an embodiment of an imaging apparatus;

FIG. 2 is a conceptual diagram showing a layout of shots on a wafer;

FIG. 3 is a conceptual diagram showing a chip layout in a shot;

FIG. 4 is a diagram showing an example of pattern design data;

FIG. 5 is a schematic diagram showing deviations between three specific points on design data and corresponding three points on images;

FIG. 6 is a flowchart illustrating an embodiment of an image generation method;

FIG. 7 is a continuation of the flowchart shown in FIG. 6;

FIG. 8 is a diagram showing an embodiment in which a specific point to be corrected is located outside a figure having vertices defined by three specific points; and

FIG. 9 is a diagram showing an embodiment in which a specific point to be corrected is located outside a figure having vertices defined by three specific points.

### DESCRIPTION OF EMBODIMENTS

Hereinafter, embodiments of the present invention will be described with reference to the drawings.

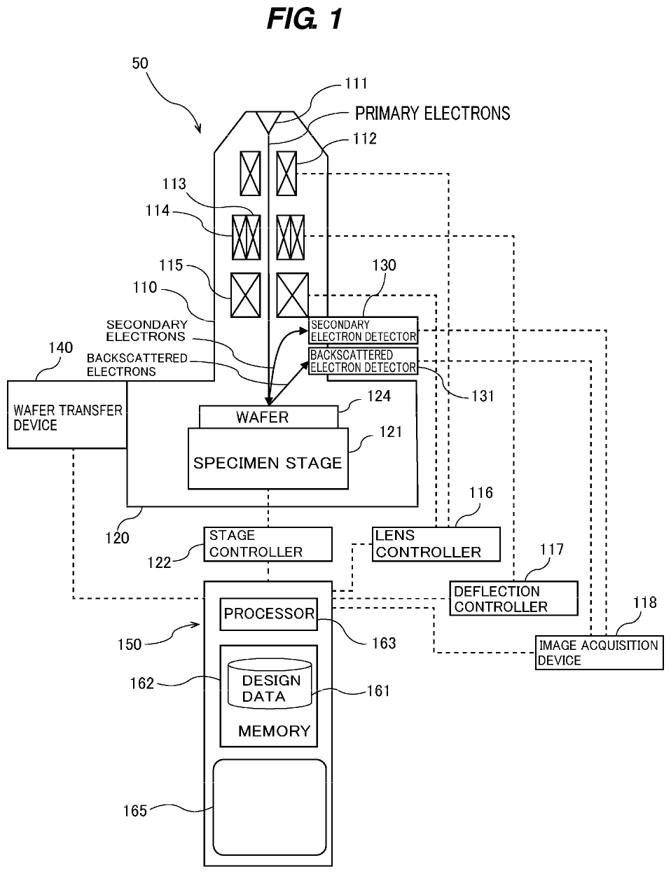

FIG. 1 is a schematic diagram showing an embodiment of an imaging apparatus. As shown in FIG. 1, the imaging apparatus includes a scanning electron microscope 50 and an arithmetic system 150. The scanning electron microscope 50 is an example of an image generation device for generating an image of an object. The scanning electron microscope 50 is coupled to the arithmetic system 150, and operations of the scanning electron microscope 50 are controlled by the arithmetic system 150.

The arithmetic system 150 includes a memory 162 storing a database 161 and programs therein, a processor 163 configured to perform arithmetic operations according to instructions included in the programs, and a display screen 165 configured to display an image, a GUI (graphical user interface), etc. The processor 163 includes a CPU (central processing unit) or a GPU (graphic processing unit) that performs arithmetic operations according to instructions included in the programs stored in the memory 162. The memory 162 includes a main memory (for example, a random access memory) accessible to the processor 163 and an auxiliary memory (for example, a hard disk drive or a solid state drive) for storing data and programs therein.

The arithmetic system 150 includes at least one computer. For example, the arithmetic system 150 may be an edge server coupled to the scanning electron microscope 50 by a communication line, or may be a cloud server coupled to the scanning electron microscope 50 by a communication network, such as the Internet or a local network, or may be a fog computing device (gateway, fog server, router, etc.) installed in a network coupled to the scanning electron microscope 50. The arithmetic system 150 may be a combination of a plurality of servers. For example, the arithmetic system 150 may be a combination of an edge server and a cloud server coupled to each other by a communication network, such as the Internet or a local network. In another example, the arithmetic system 150 may include a plurality of servers (computers) that are not connected by a network.

The scanning electron microscope 50 includes an electron gun 111 configured to emit an electron beam composed of primary electrons (charged particles), a converging lens 112 configured to converge the electron beam emitted by the electron gun 111, an X deflector 113 configured to deflect the electron beam in an X direction, a Y deflector 114 configured to deflect the electron beam in a Y direction, and an objective lens 115 configured to focus the electron beam onto a wafer 124 which is a specimen.

The converging lens 112 and the objective lens 115 are coupled to a lens controller 116, so that operations of the converging lens 112 and the objective lens 115 are controlled by the lens controller 116. The lens controller 116 is coupled to the arithmetic system 150. The X deflector 113 and the Y deflector 114 are coupled to a deflection controller 117, so that deflecting operations of the X deflector 113 and the Y deflector 114 are controlled by the deflection controller 117. The deflection controller 117 is also coupled to the arithmetic system 150 as well. A secondary electron detector 130 and a backscattered electron detector 131 are coupled to an image acquisition device 118. The image acquisition device 118 is configured to convert output signals of the secondary electron detector 130 and the backscattered electron detector 131 into images. The image acquisition device 118 is also coupled to the arithmetic system 150.

A specimen stage 121 arranged in a specimen chamber 120 is coupled to a stage controller 122, so that the position of the specimen stage 121 is controlled by the stage controller 122. The stage controller 122 is coupled to the arithmetic system 150. A wafer transporting device 140 for mounting the wafer 124 on the specimen stage 121 in the specimen chamber 120 is also coupled to the arithmetic system 150.

The electron beam emitted by the electron gun 111 is converged by the converging lens 112, and is then focused by the objective lens 115 on the surface of the wafer 124, while the electron beam is deflected by the X deflector 113 and the Y deflector 114. When the wafer 124 is irradiated with the primary electrons of the electron beam, the secondary electrons and the backscattered electrons are emitted from the wafer 124. The secondary electrons are detected by the secondary electron detector 130, and the backscattered electrons are detected by the backscattered electron detector 131. Detection signals of the secondary electrons and detection signals of the backscattered electrons signal are input to the image acquisition device 118 and converted into images. The images are transmitted to the arithmetic system 150.

Design data of patterns formed on the wafer 124 is stored in advance in the memory 162. The design data contains pattern design information, such as coordinates of vertices of each pattern formed on the wafer 124, position, shape, and size of each pattern, and the number of the layer to which each pattern belongs. A database 161 is constructed in the memory 162. The design data of patterns is stored in advance in the database 161. The arithmetic system 150 can retrieve the design data of patterns from the database 161 stored in the memory 162.

Next, an embodiment of a method of generating an image of a specific point, such as a hotspot, by the imaging apparatus will be described. Patterns on the wafer are fabricated based on the design data (which is also referred to as CAD data). CAD is an abbreviation for computer-aided design. The design data includes design information of patterns formed on the wafer. Specifically, the design data includes design information that contains coordinates of vertices of the patterns, positions, shapes, and sizes of the patterns, and the number of the layer to which each pattern belongs. A CAD pattern on the design data is a virtual pattern defined by the design information of the pattern included in the design data.

Examples of the specific point include hotspot. The hotspot is a point where a defect of a pattern is likely to occur. Hotspots can be detected by a pattern-fabricating simulation or the like. The position information of specific points (for example, hotspots), i.e., coordinates of the specific points, is input to the arithmetic system 150 and stored in the memory 162.

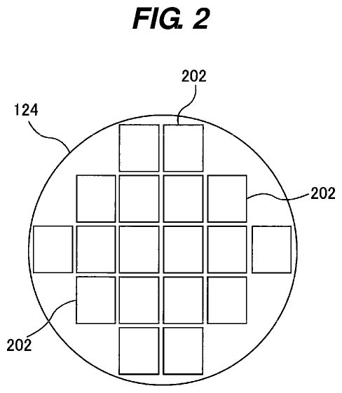

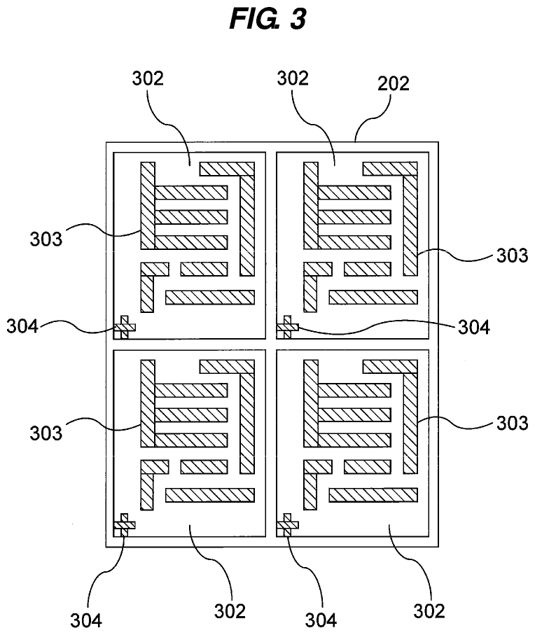

An example of the wafer 124 will be described with reference to FIGS. 2 and 3. A plurality of shots 202 are fabricated on the wafer 124. Each shot 202 is a unit for drawing photoresist patterns used for processing semiconductor devices on the wafer 124.

As shown in FIG. 3, each shot 202 can include a plurality of chips 302. Interconnect patterns 303 are formed within the chip 302. A pattern formed at the lower left of each chip 302 is a reference pattern 304.

An image of the reference pattern 304 can be used for alignment of the wafer 124. In the process of placing the wafer 124 onto the specimen stage 121, the wafer 124 may be deviated in the XY directions and a rotation direction. In order to eliminate these deviations, the alignment is performed using the image of the reference pattern 304 fabricated in advance on the wafer 124. Specifically, the reference pattern 304 in the image is matched with a corresponding CAD pattern, so that a coordinate system defined on the wafer 124 and a coordinate system defined in the design data can be matched.

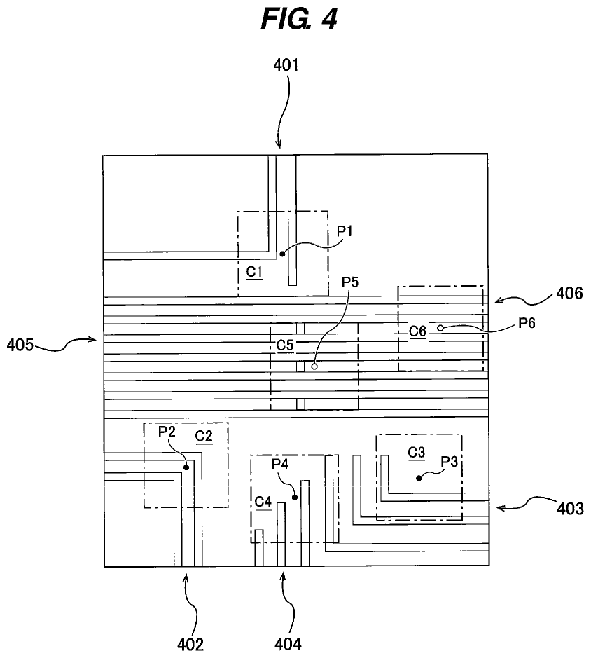

FIG. 4 is a diagram showing an example of the design data of patterns. The design data includes CAD patterns 401, 402, 403, 404, 405, 406. Specific points P1, P2, P3, P4, P5, P6 (e.g., hotspots) are plotted on the coordinate system constructed in the design data. The position of each specific point is specified by the coordinates on the coordinate system defined in the design data. In the example shown in FIG. 4, six specific points P1 to P6 are plotted on the coordinate system.

Of the specific points P1 to P6, the specific points P1, P2, P3, and P4 are adjacent to the patterns 401, 402, 403, and 404 having high aperiodicity, while the specific points P5 and P6 are adjacent to the patterns 405 and 406 having low aperiodicity. The patterns 401, 402, 403, and 404 with high aperiodicity have, in other words, distinguishing shapes which are different from shapes of surrounding patterns, and the patterns 405 and 406 with low aperiodicity have repeating shapes. In this specification, an index value indicating the aperiodicity of a pattern is referred to as uniqueness value. A high uniqueness value means that the shape of the pattern is distinguishing, and that the pattern is not a repeating pattern. On the other hand, a low uniqueness value means that the shape of the pattern is not distinguishing, and that the pattern is a repeating pattern.

The arithmetic system 150 is configured to set a plurality of clip areas C1, C2, C3, C4, C5 and C6 centered on the specific points P1, P2, P3, P4, P5 and P6, respectively, to surround each specific point with a corresponding clip area. Each clip area is an area that defines a range of pattern(s) used for calculating the uniqueness value. The size of the clip area is not particularly limited, but in one embodiment, each clip area has a size of 512 nm×512 nm, the field of view (FOV) of the scanning electron microscope 50 has a size of 512 nm×512 nm, and the positional precision of the specimen stage 121 is ±20 nm. With these specifications, it is assumed that an unpredictable image deviation of up to about ±1000 nm can occur.

The arithmetic system 150 calculates uniqueness values indicating the aperiodicity of the patterns 401, 402, 403, 404, 405, and 406 in the clip areas C1, C2, C3, C4, C5, and C6. The uniqueness value can be calculated using a known technique, such as an autocorrelation method. In the autocorrelation method, a pattern in the clip area and a pattern in an area surrounding the clip area are superposed, and a correlation coefficient of the shape between the upper and lower patterns, while one of the patterns is gradually shifted in position. The maximum value of the calculated correlation coefficient represents intensity of periodicity and can be used for calculating the uniqueness value. In one embodiment, the clip area has a size of 500 nm×500 nm, and the area surrounding the clip area is 2000 nm×2000 nm.

The arithmetic system 150 compares the uniqueness values of the patterns 401, 402, 403, 404, 405, and 406 in the clip areas C1, C2, C3, C4, C5, and C6 with a preset threshold value. The patterns 401, 402, 403, and 404 in the clip areas C1, C2, C3, and C4 containing the specific points P1, P2, P3, and P4 are not so-called repeating patterns and have distinguishing shapes. Therefore, the uniqueness values of the patterns 401, 402, 403, and 404 are higher than the threshold value. On the other hand, the patterns 405 and 406 in the clip areas C5 and C6 containing the specific points P5 and P6 are repeating patterns and do not have distinguishing shapes. Therefore, the uniqueness values of the patterns 405 and 406 are lower than the threshold value.

The arithmetic system 150 selects, from the clip areas C1 to C6, at least three clip areas in which the patterns having the uniqueness values higher than the threshold value exist. In this embodiment, the arithmetic system 150 selects the clip areas C1, C2, and C3. The arithmetic system 150 determines three specific points P1, P2, and P3 existing in the selected clip areas C1, C2, and C3, respectively. In the present embodiment, only one specific point exists in one clip area, but a plurality of specific points may exist in one clip area.

The arithmetic system 150 instructs the scanning electron microscope 50 to generate images of three points on the wafer 124 specified by the coordinates of the three specific points P1, P2, and P3. Specifically, the scanning electron microscope 50 moves the specimen stage 121 together with the wafer 124 until the specific point P1 reaches a predetermined imaging position, and then generates an image of pattern(s) in the field of view (FOV) including a point on the wafer 124 corresponding to the specific point P1. Next, the scanning electron microscope 50 moves the specimen stage 121 together with the wafer 124 until the specific point P2 reaches the predetermined imaging position, and then generates an image of pattern(s) in the field of view (FOV) including a point on the wafer 124 corresponding to the specific point P2. Further, the scanning electron microscope 50 moves the specimen stage 121 together with the wafer 124 until the specific point P3 reaches the predetermined imaging position, and then generates an image of pattern(s) in the field of view (FOV) including a point on the wafer 124 corresponding to the specific point P3.

The specific points P1, P2, P3 on the design data and the three points on the wafer 124 specified by the coordinates of these specific points P1, P2, P3 ideally match. However, as described above, due to the position error of the specimen stage 121, the charge of the wafer 124, and other causes, there are deviations between the specific points P1, P2, P3 on the design data and the three points on the wafer 124 appearing on the images. Therefore, the arithmetic system 150 obtains the three images of the three points on the wafer 124 from the scanning electron microscope 50, and calculates the deviations between the specific points P1, P2, P3 on the design data and the three points on the three images. Each deviation is represented by a vector indicating a magnitude of the deviation and a direction of the deviation.

In order to calculate the deviations, the arithmetic system 150 performs matching of the pattern (actual pattern) appearing on each image and the corresponding CAD pattern (pattern on the design data). The CAD patterns used for the matching operation are the CAD patterns 401, 402, and 403 in the clip areas C1, C2, and C3 shown in FIG. 4. Since these CAD patterns 401, 402, and 403 are distinguishing patterns (i.e., aperiodic patterns), a wide searching range can be set for the matching operation. The searching range is a region within which the arithmetic system 150 searches for a CAD pattern corresponding to a pattern on an image. In one example, the search range is a region within ±300 nm from a pattern on an image.

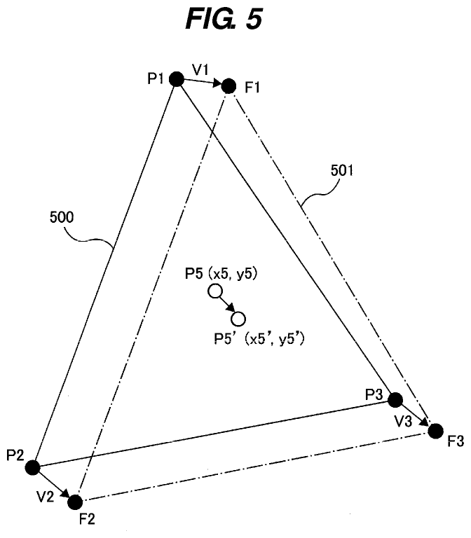

From the matching result, the arithmetic system 150 can calculate the magnitudes and directions of the deviations between the specific points P1, P2, P3 on the design data and the corresponding three points on the images. FIG. 5 is a schematic diagram showing the deviations between the specific points P1, P2, P3 on the design data and the corresponding three points F1, F2, F3 on the images. As shown in FIG. 5, the arithmetic system 150 calculates three vectors V1, V2, V3 indicating the deviations between the specific points P1, P2, P3 and the corresponding three points F1, F2, F3 on the images. Each vector indicates the magnitude and the direction of each deviation between each specific point and the corresponding point on the wafer 124.

The arithmetic system 150 calculates correction parameter(s) necessary for converting a FIG. 500 specified by the three specific points P1, P2, P3 into a figure (polygon) 501 specified by the three points F1, F2, F3 on the images. As shown in FIG. 5, the FIG. 500 is a figure having vertices defined by the specific points P1, P2, P3, and the FIG. 501 is a figure having vertices defined by the points F1, F2, F3. In the present embodiment, the arithmetic system 150 calculates the correction parameter(s) of affine transformation required to match the FIG. 500 with the FIG. 501. The correction parameter(s) includes at least one of translation distance, rotation angle, scaling percentage, and shear parameter.

The arithmetic system 150 selects, from the clip areas C1 to C6, a clip area in which a pattern having a uniqueness value equal to or less than the threshold value exists. In the present embodiment, the arithmetic system 150 selects one clip area C5 in which the pattern 405 having a uniqueness value equal to or less than the threshold value exists. The arithmetic system 150 then determines one specific point P5 existing in the clip area C5. As can be seen from FIG. 4, the specific point P5 is surrounded by the specific points P1, P2, and P3.

The arithmetic system 150 corrects the coordinates of the specific point P5 based on the vectors V1, V2, and V3. More specifically, the coordinates (x5, y5) of the specific point P5 are corrected by using the correction parameter(s) of the affine transformation necessary for matching the FIG. 500 with the FIG. 501 shown in FIG. 5. When the FIG. 500 is transformed into the FIG. 501 by the affine transformation, the specific point P5 located in the FIG. 500 moves to a specific point P5′ in the FIG. 501. The corrected coordinates of the specific point P5 are coordinates (x5′, y5′) of the specific point P5′.

The arithmetic system 150 instructs the scanning electron microscope 50 to generate an image of a point on the wafer 124 specified by the corrected coordinates (x5′, y5′) of the specific point P5. Specifically, the scanning electron microscope 50 moves the specimen stage 121 together with the wafer 124 until the specific point P5′ (x5′, y5′) reaches the predetermined imaging position, and generates an image of pattern(s) in the field of view (FOV) including the point on the wafer 124 specified by the corrected coordinates (x5′, y5′).

The arithmetic system 150 performs matching between the pattern (actual pattern) appearing on the image and the corresponding CAD pattern (pattern on the design data). The CAD pattern used for the matching operation is the CAD pattern 405 in the clip area C5 shown in FIG. 4. Since this CAD pattern 405 is a non-distinguishing pattern (i.e., a periodic pattern), it is necessary to set a narrow search range for the matching operation. In one example, the search range is a region within ±10 nm from a pattern on an image.

A pattern with a high uniqueness value is likely to succeed in matching with a corresponding actual pattern on an image. This is because the pattern having a high uniqueness value has a distinguishing shape that is different from surrounding patterns. In contrast, a pattern having a low uniqueness value has the same shape as those of surrounding patterns, and is therefore likely to fail to match with a corresponding actual pattern on an image. According to this embodiment, the coordinates of the specific points P5 are corrected based on the position information of the other three specific points P1, P2, and P3 located close to the patterns 401, 402, and 403 having high uniqueness values. Since the position information of the specific points P1, P2, and P3 used for the correction is highly reliable, the reliability of the corrected coordinates of the specific point P5 is also improved. Therefore, this method can accurately determine a position of a specific point, such as a hotspot.

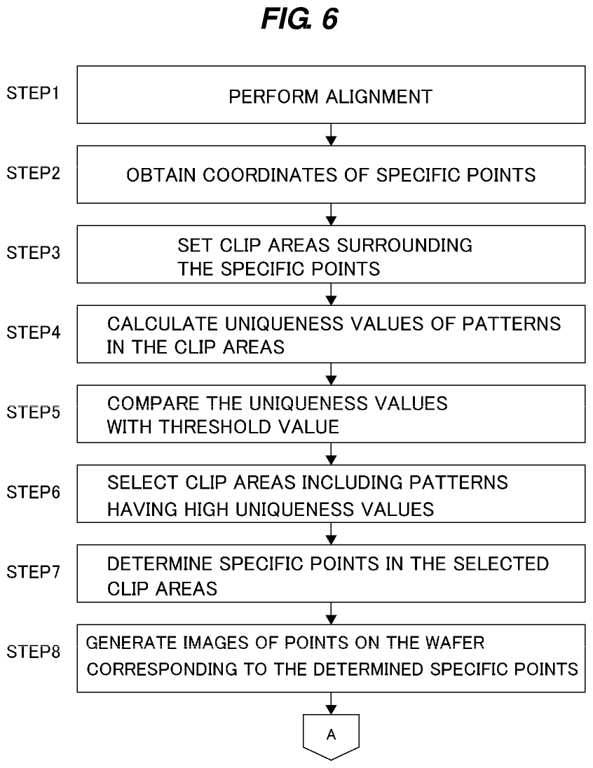

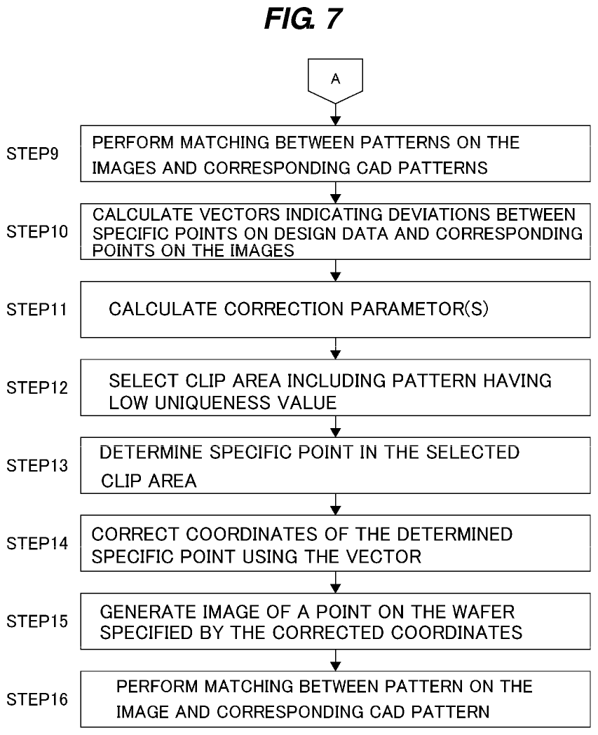

FIGS. 6 and 7 are flowcharts illustrating an embodiment of the image generation method.

In step 1, the arithmetic system 150 performs the alignment that matches the coordinate system in the design data and the coordinate system on the wafer 124 with each other. Specifically, the arithmetic system 150 instructs the scanning electron microscope 50 to generate an image of the reference pattern 304 (see FIG. 3) on the wafer 124, and obtains the image of the reference pattern 304 from the scanning electron microscope 50. Then, the arithmetic system 150 performs matching between the reference pattern 304 on the image and a corresponding CAD pattern, so that the coordinate system in the design data and the coordinate system on the wafer 124 are matched.

In step 2, the arithmetic system 150 obtains the coordinates of the specific points P1 to P6 on the design data of the patterns. In one example, the position information (i.e., the coordinates) of specific points (for example, hotspots) determined by the pattern-fabricating simulation or the like is input to the arithmetic system 150 and stored in the memory 162. In one embodiment, the arithmetic system 150 may perform the pattern-fabricating simulation, determine coordinates of the detected hotspots, and store the coordinates of the hotspots in the memory 162.

In step 3, the arithmetic system 150 sets the clip areas C1, C2, C3, C4, C5, and C6 centered on the specific points P1, P2, P3, P4, P5, and P6, so that each specific point is surrounded by each clip area.

In step 4, the arithmetic system 150 calculates the uniqueness values indicating the aperiodicity of the patterns 401 to 406 in the clip areas C1 to C6.

In step 5, the arithmetic system 150 compares the uniqueness values of the patterns 401 to 406 in the clip areas C1 to C6 with the preset threshold value.

In step 6, the arithmetic system 150 selects three clip areas C1, C2, and C3 in which patterns 401, 402, and 403 having uniqueness values higher than the threshold value exist.

In step 7, the arithmetic system 150 determines three specific points P1, P2, and P3 existing in the three clip areas C1, C2, and C3, respectively.

In step 8, the arithmetic system 150 instructs the scanning electron microscope 50 to generate images of the three points F1, F2, and F3 on a chip specified by the coordinates of the three specific points P1, P2, and P3. The three images generated include not only the three points F1, F2, F3 on the chip, but also patterns existing around the three points F1, F2, F3.

In step 9, the arithmetic system 150 obtains the three images of the three points F1, F2, F3 and the surrounding patterns on the wafer 124 from the scanning electron microscope 50. The arithmetic system 150 then performs matching between the patterns appearing on the three images and the corresponding CAD patterns.

In step 10, the arithmetic system 150 calculates the vectors V1, V2, V3 indicating the deviations between the specific points P1, P2, P3 on the design data and the three points F1, F2, F3 on the three images.

In step 11, the arithmetic system 150 calculates the correction parameter(s) necessary for converting the FIG. 500 specified by the three specific points P1, P2, P3 into the FIG. 501 specified by the three points F1, F2, F3 on the images.

In step 12, the arithmetic system 150 selects the clip area C5 in which the pattern 405 having the uniqueness value equal to or less than the threshold value exists.

In step 13, the arithmetic system 150 determines the specific point P5 existing in the clip area C5.

In step 14, the arithmetic system 150 corrects the coordinates of the specific point P5 based on the vectors V1, V2, and V3. More specifically, the arithmetic system 150 corrects the coordinates (x5, y5) of the specific point P5 using the correction parameter(s) of the affine transformation necessary for matching the FIG. 500 with the FIG. 501 shown in FIG. 5.

In step 15, the arithmetic system 150 instructs the scanning electron microscope 50 to generate an image of a point on the chip specified by the corrected coordinates (x5′, y5′) of the specific point P5. The generated image includes pattern(s) that exists around the point on the chip specified by the coordinates (x5′, y5′).

In step 16, the arithmetic system 150 performs matching between the pattern (actual pattern) appearing on the image generated in the step 15 and a corresponding CAD pattern.

In the above-described embodiment, three specific points P1, P2, and P3 are used, but in one embodiment, four or more specific points existing in four or more clip areas with patterns having high uniqueness values may be used.

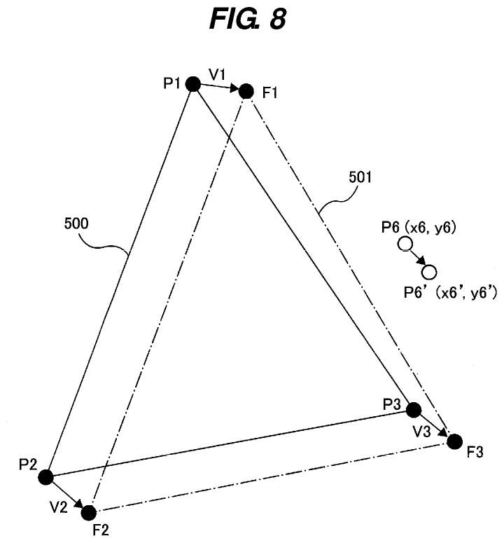

In one embodiment, in the step 12, the arithmetic system 150 may select the clip area C6 (see FIG. 4) in which the pattern 406 having a uniqueness value equal to or less than the threshold value exists, and in the step 13, the arithmetic system 150 may determine the specific point P6 (see FIG. 4) existing in the clip area C6. As shown in FIG. 4, the specific point P6 is not surrounded by the specific points P1, P2, P3. Specifically, as shown in FIG. 8, the specific point P6 is located outside the FIG. 500 having vertices defined by the specific points P1, P2, and P3. When a distance between the specific point P6 and the FIG. 500 specified by the specific points P1, P2 and P3 is less than or equal to a predetermined distance, the coordinates (x6, y6) of the specific point P6 are corrected based on the vectors V1, V2 and V3. Specifically, the arithmetic system 150 corrects the coordinates (x6, y6) of the specific point P6 by using the correction parameter(s) of the affine transformation necessary for matching the FIG. 500 with the FIG. 501.

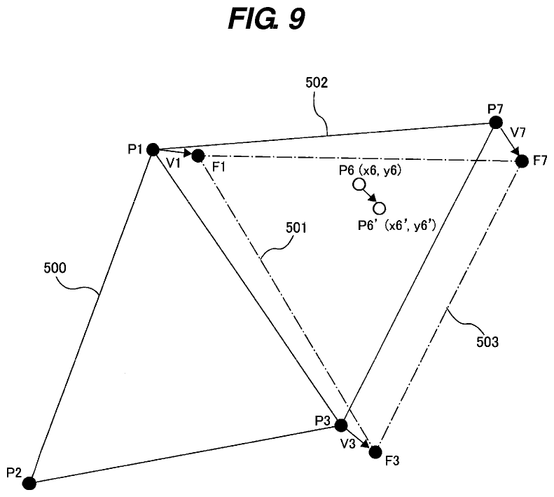

As shown in FIG. 9, when the distance between the specific point P6 and the FIG. 500 specified by the specific points P1, P2, and P3 is larger than the predetermined distance, the arithmetic system 150 newly determines a specific point P7 in a clip area in which a pattern having a high uniqueness value exists. The specific point P7 is such that the specific point P6 is surrounded by the specific points P1, P3, P7, i.e., the specific point P6 is located in a FIG. 502 specified by the specific points P1, P3, P7. The specific point P7 can be added by searching the design data for a CAD pattern having a uniqueness value equal to or higher than the threshold value.

The arithmetic system 150 instructs the scanning electron microscope 50 to generate an image of a point F7 on a chip specified by the coordinates of the specific point P7. Further, the arithmetic system 150 calculates a vector V7 indicating the magnitude and the direction of the deviation between the specific point P7 and the corresponding point F7 on the image. Then, the arithmetic system 150 corrects the coordinates (x6, y6) of the specific point P6 based on the vectors V1, V3, and V7. More specifically, the arithmetic system 150 corrects the coordinates (x6, y6) of the specific point P6 by using the correction parameter(s) of the affine transformation necessary for matching the FIG. 502 with a FIG. 503. The FIG. 503 is a figure specified by three points F1, F3, and F7 on the images.

In this way, by appropriately setting at least three specific points surrounding the specific point P6 to be corrected or at least three specific points located near the specific point P6 to be corrected, the coordinates of the specific point P6 can be corrected with high accuracy.

Depending on the configuration of the pattern in the chip, at least three specific points surrounding the specific point P6 to be corrected may not exist. In such a case, the arithmetic system 150 calculates a distance from the specific point P1 (which is closest to the specific point P6) to the specific point P6. If the calculated distance is less than or equal to a preset distance, the arithmetic system 150 corrects the coordinates of the specific point P6 based on the vector V1 indicating the deviation between the specific point P1 and the point F1. More specifically, the arithmetic system 150 corrects the coordinates of the specific point P6 by moving the specific point P6 in the direction indicated by the vector V1 by the distance indicated by the vector V1.

The previous description of embodiments is provided to enable a person skilled in the art to make and use the present invention. Moreover, various modifications to these embodiments will be readily apparent to those skilled in the art, and the generic principles and specific examples defined herein may be applied to other embodiments. Therefore, the present invention is not intended to be limited to the embodiments described herein but is to be accorded the widest scope as defined by limitation of the claims.

### Industrial Applicability

The present invention is applicable to a method of imaging a specific point on a wafer using a scanning electron microscope.

### Reference Signs List

50 scanning electron microscope
111 electron gun
112 converging lens
113 X deflector
114 Y deflector
115 objective lens
116 lens controller
117 deflection controller
118 image acquisition device
121 specimen stage
122 stage controller
124 wafer
130 secondary electron detector
131 backscattered electron detector
140 wafer transporting device
150 arithmetic system
161 database
162 memory
163 processor
165 display screen
202 shot
302 chip
304 reference pattern
401, 402, 403, 404, 405, 406 CAD pattern
P1, P2, P3, P4, P5, P6 specific point
C1, C2, C3, C4, C5, C6 clip area

1. An image generation method comprising:
setting clip areas centered on specific points on a design data of patterns;
calculating uniqueness values each indicating an aperiodicity of a pattern in each of the clip areas;
comparing the uniqueness values with a preset threshold value;
selecting, from the clip areas, a clip area in which a pattern having a uniqueness value higher than the threshold value exists;
determining a first specific point which is a specific point existing in the selected clip area;
generating an image of a first point on a chip by a scanning electron microscope, the first point being specified by coordinates of the first specific point;
calculating a vector indicating deviation between the first specific point and the first point on the image;
correcting coordinates of a second specific point based on the vector, the second specific point being in a clip area in which a pattern having a uniqueness value equal to or less than the threshold value exists; and
generating an image of a second point on the chip by the scanning electron microscope, the second point being specified by the corrected coordinates.

2. The image generation method according to claim 1, further comprising:
performing a first matching between a pattern appearing on the image of the first point on the chip and a corresponding CAD pattern; and
performing a second matching between a pattern appearing on the image of the second point on the chip and a corresponding CAD pattern;
wherein a search range for searching for the corresponding CAD pattern in the second matching is narrower than a search range for searching for the corresponding CAD pattern in the first matching.

3. The image generation method according to claim 1, wherein:
the selected clip area comprises at least three clip areas selected from the clip areas;
the first specific point comprises at least three first specific points existing in the at least three clip areas, respectively;
the first point comprises at least three first points on the chip specified by coordinates of the at least three first specific points; and
the vector comprises vectors indicating deviations between the at least three first specific points and the at least three first points on the image.

4. The image generation method according to claim 3, wherein the second specific point is surrounded by the at least three first specific points.

5. The image generation method according to claim 3, wherein the second specific point is located outside a figure having vertices defined by the at least three first specific points.

6. The image generation method according to claims 3, wherein correcting the coordinates of the second specific point based on the vectors comprises:
calculating a correction parameter necessary for converting a figure specified by the at least three first specific points into a figure specified by the at least three first points on the image; and
correcting the coordinates of the second specific point using the correction parameter.

7. The image generation method according to claim 1, wherein a distance from the first specific point to the second specific point is equal to or less than a preset distance.

8. The image generation method according to claim 7, wherein correcting the coordinates of the second specific point based on the vector comprises correcting the coordinates of the second specific point by moving the second specific point in a direction indicated by the vector by a distance indicated by the vector.

9. The image generation method according to claim 2, wherein:
the selected clip area comprises at least three clip areas selected from the clip areas;
the first specific point comprises at least three first specific points existing in the at least three clip areas, respectively;
the first point comprises at least three first points on the chip specified by coordinates of the at least three first specific points; and
the vector comprises vectors indicating deviations between the at least three first specific points and the at least three first points on the image.

10. The image generation method according to claim 4, wherein correcting the coordinates of the second specific point based on the vectors comprises:
calculating a correction parameter necessary for converting a figure specified by the at least three first specific points into a figure specified by the at least three first points on the image; and
correcting the coordinates of the second specific point using the correction parameter.

11. The image generation method according to claim 5, wherein correcting the coordinates of the second specific point based on the vectors comprises:
calculating a correction parameter necessary for converting a figure specified by the at least three first specific points into a figure specified by the at least three first points on the image; and
correcting the coordinates of the second specific point using the correction parameter.

12. The image generation method according to claim 2, wherein a distance from the first specific point to the second specific point is equal to or less than a preset distance.
